(19) United States
(12) Patent Application Publication
(10) Pub. No.: US 2025/0274018 A1
(43) Pub. Date: Aug. 28, 2025

(54) ELECTRIC COMPRESSOR

(71) Applicant: KABUSHIKI KAISHA TOYOTA JIDOSHOKKI, Aichi (JP)

(72) Inventors: Yoshifumi TADA, Aichi (JP); Katsuya USAMI, Aichi (JP); Atsushi OSHIMA, Aichi (JP); Kenta MATSUOKA, Aichi (JP)

(73) Assignee: KABUSHIKI KAISHA TOYOTA JIDOSHOKKI, Aichi (JP)

(21) Appl. No.: 19/062,654

(22) Filed: Feb. 25, 2025

(30) Foreign Application Priority Data
Feb. 28, 2024 (JP) 2024-028332

(51) Int. Cl. H02K 11/02; F25B 31/02; H02K 11/33; H03H 7/01

(52) U.S. Cl. CPC H02K 11/02; F25B 31/02; H02K 11/33; H03H 7/0115; H02K 2211/03

(57) ABSTRACT

An electric compressor includes: a rotary shaft; an inverter that includes a second circuit board having a plurality of electronic components; and a housing that includes a motor housing. The motor housing has a projected portion projecting outward from the motor housing in a radial direction of the rotary shaft, having a bottomed-cylindrical shape with an opening, and extending in an insertion direction of the second circuit board. The electronic components protrude from the second circuit board and are arranged in the insertion direction in ascending order of protrusion height from the second circuit board. The projected portion has a protrusion portion facing the electronic components and protruding toward the electronic components in the radial direction, with protrusion height of the protrusion portion increasing in the insertion direction correspondingly with an arrangement of the electronic components. A heat transfer member is provided between the protrusion portion and the electronic components.

### CROSS-REFERENCE TO RELATED APPLICATION

This application claims priority to Japanese Patent Application No. 2024-028332 filed on Feb. 28, 2024, the entire disclosure of which is incorporated herein by reference.

The present disclosure relates to an electric compressor.

### BACKGROUND ART

Japanese Patent Application Publication No. 2014-058910 discloses an electric compressor that includes a rotary shaft, a compression part configured to compress a fluid with rotation of the rotary shaft, a motor configured to drive the compression part, an inverter configured to drive the motor, and a housing. The housing accommodates the rotary shaft, the compression part, the motor, and the inverter. The inverter includes a first circuit board and a second circuit board. The first circuit board has, on the first circuit board, a driving element for driving the motor. The second circuit board has, on the second circuit board, an electronic component for removing noise from the first circuit board. The first circuit board is accommodated in a first accommodation chamber, and the second circuit board is accommodated in a second accommodation chamber.

Such an electric compressor may include a heat transfer member disposed between the electronic component of the second circuit board and a fixing surface of the second accommodation chamber to which the electronic component is fixed. When the second circuit board and the electronic component are mounted to the housing, the second circuit board and the electronic component may be moved in the axial direction of the rotary shaft in the second accommodation chamber. If the electronic component is moved while coming into contact with the fixing surface of the second accommodation chamber, the thickness of the heat transfer member may exhibit unevenness.

The present disclosure is directed to providing an electric compressor in which thickness unevenness of a heat transfer member is reduced.

### SUMMARY

In accordance with an aspect of the present disclosure, there is provided an electric compressor that includes: a rotary shaft; a compression part; a motor configured to drive the compression part; an inverter; and a housing for accommodating the rotary shaft, the compression part, the motor, and the inverter. The compression part is configured to compress a fluid with rotation of the rotary shaft. The inverter is configured to drive the motor. The inverter includes a first circuit board and a second circuit board. The first circuit board has, on the first circuit board, a driving element for driving the motor. The second circuit board has, on the second circuit board, an electronic component for removing noise from the first circuit board. The housing includes: a motor housing having a suction chamber in which the motor is accommodated and into which the fluid is drawn; a compression part housing in which the compression part is accommodated and from which the fluid compressed is discharged; an inverter housing having an inverter accommodation chamber in which the inverter is accommodated; and a partition wall that separates the suction chamber from the inverter accommodation chamber. The motor housing has a projected portion projecting outward from the motor housing in a radial direction of the rotary shaft and having a bottomed-cylindrical shape with an opening that opens in an axial direction of the rotary shaft. The projected portion extends in an insertion direction of the second circuit board in which the second circuit board is inserted into the projected portion through the opening from a side where the partition wall is located. The electronic component includes a plurality of the electronic components that protrude from the second circuit board and are arranged in the insertion direction of the second circuit board toward a bottom portion of the projected portion in ascending order of protrusion height from the second circuit board. The projected portion has a protrusion portion facing the electronic components and protruding toward the electronic components in the radial direction of the rotary shaft, with protrusion height of the protrusion portion increasing in the insertion direction of the second circuit board toward the bottom portion of the projected portion correspondingly with an arrangement of the electronic components. A heat transfer member is provided between the protrusion portion and the electronic components.

Other aspects and advantages of the disclosure will become apparent from the following description, taken in conjunction with the accompanying drawings, illustrating by way of example the principles of the disclosure.

### BRIEF DESCRIPTION OF THE DRAWINGS

The disclosure, together with objects and advantages thereof, may best be understood by reference to the following description of the embodiments together with the accompanying drawings in which:

FIG. 1 is a sectional view of an electric compressor according to an embodiment;

FIG. 2 is a sectional view of a part of the electric compressor;

FIG. 3 is a sectional view of a part of the electric compressor; and

FIG. 4 is a sectional view of a part of the electric compressor, explaining a method of mounting a second circuit board, a capacitor, and a magnetic component to a housing.

### DETAILED DESCRIPTION OF THE EMBODIMENTS

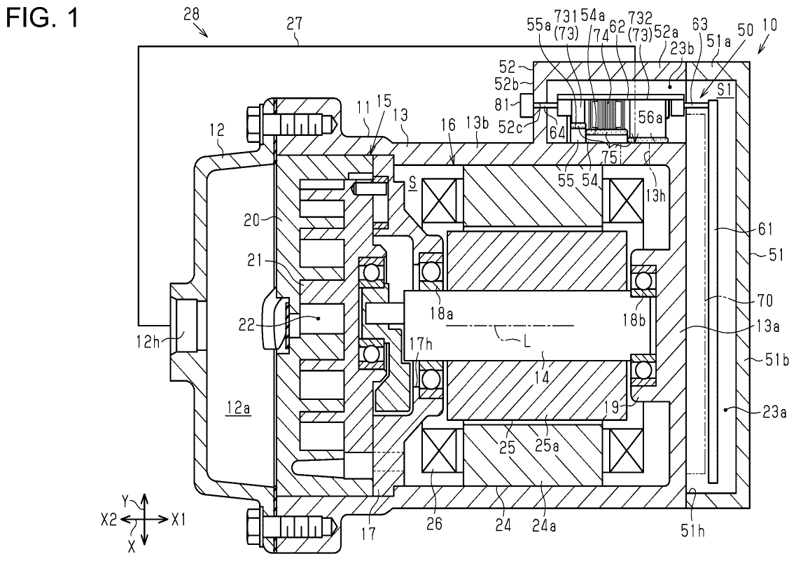

The following will describe an embodiment of an electric compressor with reference to accompanying FIGS. 1 to 4. The electric compressor of the embodiment is applied, for example, to a vehicle air conditioner.

FIG. 1 illustrates an electric compressor 10 that includes a housing 11. The housing 11 includes a discharge housing 12, a motor housing 13, and an inverter housing 51. The discharge housing 12, the motor housing 13, and the inverter housing 51 are each made of a metal material. The discharge housing 12, the motor housing 13, and the inverter housing 51 are each made of aluminum, for example. The discharge housing 12 has a cylindrical shape. The motor housing 13 includes an end wall 13a having a plate-like shape, a peripheral wall 13b having a cylindrical shape, and a projected portion 52. The peripheral wall 13b has a cylindrical shape and extends from an outer peripheral portion of the end wall 13a. The projected portion 52 has a bottomed-cylindrical shape.

The electric compressor 10 includes a rotary shaft 14. The rotary shaft 14 is accommodated in the motor housing 13.

The electric compressor 10 includes a compression part 15, a motor 16, and an inverter 50. The compression part 15 and the motor 16 are accommodated in the motor housing 13. The compression part 15 is driven by rotation of the rotary shaft 14. The compression part 15 compresses a refrigerant as a fluid with the rotation of the rotary shaft 14. The motor 16 rotates the rotary shaft 14 to drive the compression part 15. The compression part 15 and the motor 16 are arranged side by side in an axial direction X of the rotary shaft 14, which is indicated by an axis L. The motor 16 is disposed between the compression part 15 and the end wall 13a of the motor housing 13.

The electric compressor 10 includes a shaft support member 17. The shaft support member 17 is disposed between the compression part 15 and the motor in the motor housing 13. The shaft support member 17 has an insertion hole 17h. The insertion hole 17h is formed at a center portion of the shaft support member 17. A first end of the rotary shaft 14 is inserted through the insertion hole 17h. A bearing 18a is disposed between the insertion hole 17h and the first end of the rotary shaft 14. The first end of the rotary shaft 14 is rotatably supported by the shaft support member 17 via the bearing 18a.

The motor housing 13 has a bearing holding portion 19 having a cylindrical shape. The bearing holding portion 19 protrudes from a center portion of the end wall 13a of the motor housing 13. A second end of the rotary shaft 14 is inserted into the bearing holding portion 19. A bearing 18b is disposed between the bearing holding portion 19 and the second end of the rotary shaft 14. The second end of the rotary shaft 14 is rotatably supported by the bearing holding portion 19 via the bearing 18b.

The compression part 15 includes a fixed scroll 20 and a movable scroll 21. The fixed scroll 20 is fixed to an inner peripheral surface of the peripheral wall 13b of the motor housing 13. The movable scroll 21 faces the fixed scroll 20. The fixed scroll 20 and the movable scroll 21 mesh with each other. The fixed scroll 20 and the movable scroll 21 cooperate to define a compression chamber 22 with variable volume. The compression chamber 22 compresses the refrigerant drawn, and discharges the refrigerant.

The motor 16 includes a stator 24 having a cylindrical shape and a rotor 25 having a cylindrical shape. The rotor 25 is disposed inside the stator 24. The rotor 25 rotates together with the rotary shaft 14. The stator 24 surrounds the rotor 25. The rotor 25 includes a rotor core 25a fixed to the rotary shaft 14, and a plurality of permanent magnets (not illustrated) disposed in the rotor core 25a. The stator 24 includes a cylindrical stator core 24a and a coil 26 wound around the stator core 24a. When power is supplied to the coil 26, the rotor 25 and the rotary shaft 14 rotate.

The motor housing 13 has a suction port 13h. The suction port 13h is formed in the peripheral wall 13b. The refrigerant is drawn into the motor housing through the suction port 13h. The suction port 13h is connected to a first end of an external refrigerant circuit 27. The discharge housing 12 has a discharge chamber 12a. The discharge housing 12 has a discharge port 12h. The discharge port 12h is communicated with the discharge chamber 12a. The discharge port 12h is connected to a second end of the external refrigerant circuit 27.

The refrigerant is drawn from the external refrigerant circuit 27 into the motor housing 13 through the suction port 13h. The motor housing 13 has a suction chamber S. In other words, the motor housing 13 has the suction chamber S in which the motor 16 is accommodated and into which the fluid is drawn. The refrigerant drawn into the suction chamber S in the motor housing 13 is further ( ) drawn into the compression chamber 22 through the orbiting motion of the movable scroll 21. The refrigerant in the compression chamber 22 is compressed with the orbiting motion of the movable scroll 21. The refrigerant compressed in the compression chamber 22 is then discharged into the discharge chamber 12a. That is, the refrigerant compressed by the compression part 15 is discharged from the motor housing 13 to the discharge chamber 12a. Accordingly, the motor housing also serves as the compression part housing of the present disclosure from which the fluid compressed is discharged. The discharge chamber 12a is a discharge pressure region. The refrigerant discharged to the discharge chamber 12a flows out to the external refrigerant circuit 27 through the discharge port 12h. The refrigerant flows through a heat exchanger and an expansion valve of the external refrigerant circuit 27, and returns to the motor housing 13 through the suction port 13h. The electric compressor 10 and the external refrigerant circuit 27 cooperate to form a vehicle air conditioner 28.

The inverter housing 51 has an open end that is open toward the end wall 13a and the projected portion 52. The open end of the inverter housing 51 is attached to the end wall 13a and the projected portion 52, so that the inverter housing 51 is attached to the motor housing 13. The inverter housing 51 and the projected portion 52 cooperate to define a space that partly serves as an inverter accommodation chamber S1 for accommodating the inverter 50. That is, the housing 11 includes the inverter housing 51 that defines the inverter accommodation chamber S1 for accommodating the inverter 50. The end wall 13a of the motor housing 13 serves as the partition wall of the present disclosure that separates the suction chamber S from the inverter accommodation chamber S1.

The axial direction X includes opposite directions that serve as a first axial direction X1 and a second axial direction X2, respectively. In the axial direction X, the first axial direction X1 is oriented toward a first side, and the second axial direction X2 is oriented toward a second side. The inverter housing 51 has a first cylindrical portion 51a having a cylindrical shape and extending in the axial direction X, and a closing portion 51b. The first cylindrical portion 51a has opposite ends 10) that define the first cylindrical portion 51a in the axial direction X. One of the opposite ends of the first cylindrical portion 51a on the first side is closed by the closing portion 51b. The first cylindrical portion 51a has, for example, a cylindrical shape. The closing portion 51b has, for example, a flat plate shape and extends perpendicular to the axial direction X. The inverter housing 51 has a first open portion 51h that opens in the second axial direction X2. The first open portion 51h is an open end of the first cylindrical portion 51a that opens in the second axial direction X2.

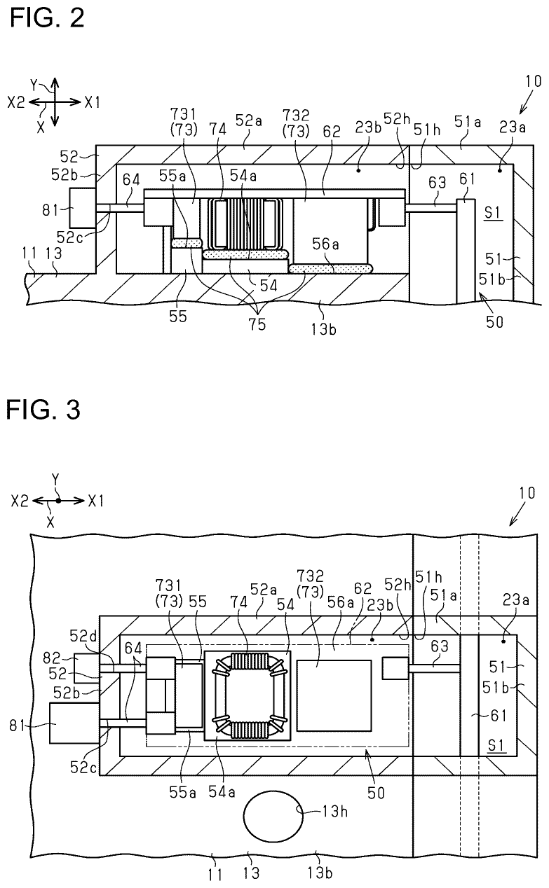

As illustrated in FIGS. 2 and 3, the projected portion 52 has a second cylindrical portion 52a having a cylindrical shape and extending in the axial direction X, and a bottom portion 52b. The second cylindrical portion 52a has opposite ends that define the second cylindrical portion 52a in the axial direction X. One of the opposite ends of the second cylindrical portion 52a on the second side is closed by the bottom portion 52b. The bottom portion 52b has, for example, a flat plate shape and extends perpendicular to the axial direction X. The bottom portion 52b has a first through hole 52c and a second through hole 52d. The projected portion 52 has a second open portion 52h that opens in the first axial direction X1. The second open portion 52h is an open end of the second cylindrical portion 52a on the first side. In other words, the second open portion 52h serves as the opening of the present disclosure through which the second circuit board 62 is inserted.

As illustrated in FIG. 1, in this embodiment, a part of the second cylindrical portion 52a is connected to the peripheral wall 13b of the motor housing 13. The second cylindrical portion 52a may be integrally formed with the peripheral wall 13b, or may be separately formed from and connected to the peripheral wall 13b. Furthermore, the part of the second cylindrical portion 52a may be a part of the peripheral wall 13b. Accordingly, the motor housing 13 has a projected portion 52 projecting outward from the motor housing 13 in a radial direction of the rotary shaft and having a bottomed-cylindrical shape.

The first open portion 51h partly faces the second open portion 52h in the axial direction X. According to this configuration, the inside of the projected portion is connected to the inside of the inverter housing 51 via the first open portion 51h and the second open portion 52h, and the inverter accommodation chamber S1 is formed inside the projected portion 52 and the inverter housing 51. A part of the first open portion 51h that does not face the second open portion 52h in the axial direction X is closed by the end wall 13a of the motor housing 13.

The inverter housing 51 and the end wall 13a of the motor housing 13 cooperate to define a first accommodation chamber 23a. The projected portion 52 and the peripheral wall 13b of the motor housing 13 cooperate to define a second accommodation chamber 23b.

The inverter 50 for driving the motor 16 includes a first circuit board 61 and a second circuit board 62. The first circuit board 61 has, on the first circuit board 61, a driving element 70 for driving the motor 16. The second circuit board 62 has, on the second circuit board 62, a pair of capacitors 73 and a magnetic component 74, which serve as the plurality of electronic components of the present disclosure for removing noise from the first circuit board 61.

For example, the first circuit board 61 and the second circuit board 62 each have a flat plate shape. The first circuit board 61 extends in an orthogonal direction Y that is a direction perpendicular to the axis L of the rotary shaft 14. The second circuit board 62 extends in the axial direction X of the rotary shaft 14, which is indicated by the axis L.

The first circuit board 61 is disposed in the first accommodation chamber 23a. That is, the inverter housing 51 accommodates the first circuit board 61. The second circuit board 62 is disposed in the second accommodation chamber 23b. That is, the projected portion 52 accommodates the second circuit board 62. The second circuit board 62 is inserted through the second open portion 52h of the projected portion 52, and arranged along the axial direction X in the projected 10) portion 52. Accordingly, the motor housing 13 has the projected portion 52 projecting outward from the motor housing 13 in the radial direction of the rotary shaft 14 and having a bottomed-cylindrical shape with the second open portion 52h that opens in the first axial direction X1. The projected portion 52 extends in an insertion direction of the second circuit board 62 in which the second circuit board 62 is inserted into the projected portion 52 through the second open portion 52h from a side where the end wall 13a is located (i.e., the side where the partition wall is located).

The first circuit board 61 and the second circuit board 62 are connected to each other by a wire 63. The wire 63 extends, for example, between the first accommodation chamber 23a and the second accommodation chamber 23b.

As illustrated in FIGS. 2 and 3, the second circuit board 62 has two wires 64. The two wires 64 respectively extend through the first through hole 52c and the second through hole 52d from the second accommodation chamber 23b to the outside of the housing 11.

The wire 64 inserted through the first through hole 52c is connected to a high-voltage connector 81 outside the housing 11. The high-voltage connector 81 is connected to a connector of a high-voltage power supply as an external power supply (not illustrated), for example. The wire 64 inserted through the second through hole 52d is connected to a low-voltage connector 82 outside the housing 11. The low-voltage connector 82 is connected to a connector of a low-voltage power supply (not illustrated), for example.

As illustrated in FIG. 1, the first circuit board 61 has, on the first circuit board 61, the driving element 70 for driving the motor 16. In FIG. 1, the driving element is illustrated in simplified form with a two-dot line. The driving element 70 may be formed of multiple parts. The pair of capacitors 73 and the magnetic component (i.e., the electronic components) are mounted on the second circuit board 62.

On the second circuit board 62, the magnetic component 74 is disposed between the capacitors 73 in the axial direction X, as illustrated in FIG. 3. When viewed from the orthogonal direction Y, the pair of capacitors 73 and the magnetic component 74 are aligned in a straight line in the axial direction X. For example, the pair of capacitors 73 and the magnetic component 74 are arranged so that the centers of the capacitors 73 and the magnetic component 74 are aligned in a straight line in the axial direction X when viewed from the orthogonal direction Y. One and the other of the capacitors 73 serve as a first capacitor 731 and a second capacitor 732, respectively. The first capacitor 731 is smaller than the magnetic component 74 in the orthogonal direction Y, and the second capacitor 732 is larger than the magnetic component 74 in the orthogonal direction Y.

The second circuit board 62 is inserted into the projected portion 52 through the second open portion 52h toward the bottom portion 52b of the projected portion 52. The pair of capacitors 73 and the magnetic component 74 protrude from the second circuit board 62 and are arranged in the insertion direction of the second circuit board 62 toward the bottom portion 52b of the projected portion 52 in ascending order of protrusion height from the second circuit board 62, from the most protruding near the second open portion 52h to the least protruding near the bottom portion 52b. Specifically, in the first axial direction X1, the first capacitor 731, the magnetic component 74, and the second capacitor 732 are arranged on the second circuit board 62 in descending order of protrusion height from the second circuit board 62, from the least protruding to the most protruding.

As illustrated in FIG. 2, in this embodiment, the projected portion 52 has inside a first protrusion portion 54 and a second protrusion portion 55. For example, the first protrusion portion 54 and the second protrusion portion 55 each have a columnar shape and extend in the orthogonal direction Y from the inner peripheral surface of the second cylindrical portion 52a. The first protrusion portion 54 has a first fixing surface 54a at the distal end of the first protrusion portion 54. The second protrusion portion 55 has a second fixing surface 55a at the distal end of the second protrusion portion 55. In the orthogonal direction Y, the first fixing surface 54a is positioned between the second fixing surface 55a and the motor housing 13. The peripheral wall 13b of the motor housing 13 has a third fixing surface 56a inside projected portion 52. The third fixing surface 56a is located next to the first protrusion portion 54 in the first axial direction X1, and positioned between the first fixing surface 54a and the motor housing 13 in the orthogonal direction Y. The third fixing surface 56a is not on the protrusion portion of the present disclosure, and is a part of the outer peripheral surface of the peripheral wall 13b.

The first protrusion portion 54 and the second protrusion portion 55 cooperate to serve as the protrusion portion of the present disclosure, and the protrusion height of the first protrusion portion 54 from the motor housing 13 is lower than the protrusion height of the second protrusion portion 55 from the motor housing 13. That is, the protrusion portion of the present disclosure increases in a direction from the second open portion 52h toward the bottom portion 52b of the projected portion 52. The third fixing surface 56a, the first fixing surface 54a, and the second fixing surface 55a are arranged in this order in the direction from the second open portion 52h toward the bottom portion 52b. In the orthogonal direction Y, the second fixing surface 55a is closest to the second circuit board 62, followed by the first fixing surface 54a, and the third fixing surface 56a in this order.

The magnetic component 74 is fixed to the first fixing surface 54a via the heat transfer member of the present disclosure, which, in this embodiment, is a potting compound 75. The first capacitor 731 and the second capacitor 732 are fixed to the second fixing surface 55a and the third fixing surface 56a via the potting compound 75.

The magnetic component 74 faces the first protrusion portion 54 of the projected portion 52 in the radial direction of the rotary shaft 14. The first capacitor faces the second protrusion portion 55 of the projected portion 52 in the radial direction of the rotary shaft 14. The second protrusion portion 55 is located between the first protrusion portion 54 and the bottom portion 52b. The potting compound 75 is provided between the magnetic component 74 and the first protrusion portion 54 and between the first capacitor 731 and the second protrusion portion 55.

The first protrusion portion 54 faces the second capacitor 732 in the axial direction X of the rotary shaft 14. The second protrusion portion 55 faces the magnetic component 74 in the axial direction X. The potting compound 75 is provided between the first protrusion portion 54 and the second capacitor 732, and is also provided between the second protrusion portion 55 and the magnetic component 74 in the axial direction X. The potting compound 75 allows heat transfer between the peripheral wall 13b of the motor housing 13 and the capacitors and the magnetic component 74 via the potting compound 75. Since the refrigerant flows within the motor housing 13, the capacitors 73 and the magnetic component 74 are cooled by the heat transfer.

The following will describe the operation of the electric compressor according to the embodiment, with reference to a method for mounting the second circuit board 62 to the housing 11.

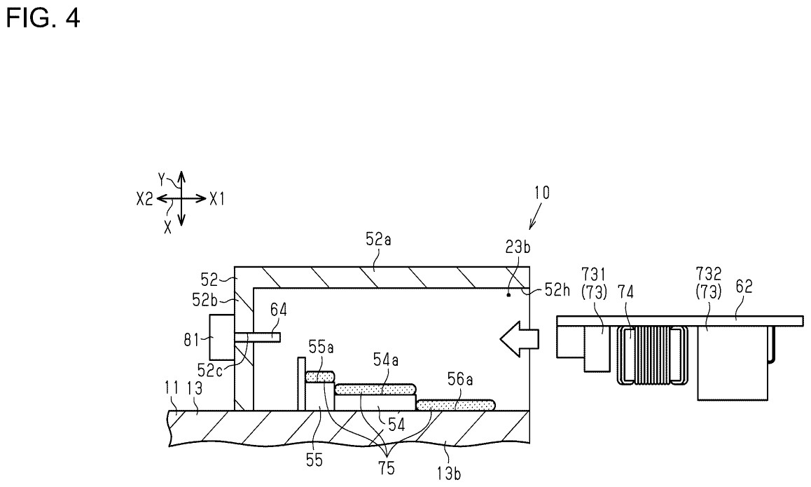

As illustrated in FIG. 4, firstly, the capacitors 73 and the magnetic component 74 are mounted on the second circuit board 62 integrally. Then, the second circuit board 62 integrated with the capacitors 73 and the magnetic component 74 is mounted to the housing 11. At this time, the inverter housing 51 is not attached to the housing 11. That is, the second open portion 52h of the projected portion 52 is open to the outside of the housing 11. The second circuit board 62 integrated with the capacitors 73 and the magnetic component 74 is inserted into the projected portion 52 through the second open portion 52h. Accordingly, in the projected portion 52, the capacitors 73 and the magnetic component 74 integrated with the second circuit board 62 are moved in the second axial direction X2.

The capacitors 73 and the magnetic component 74 protrude from the second circuit board 62, and are arranged in the first axial direction X1 so that the first capacitor 731, the magnetic component 74, and the second capacitor 732 are arranged on the second circuit board 62 in descending order of protrusion height from the second circuit board 62. In the projected portion 52, the second fixing surface 55a, the first fixing surface 54a, and the third fixing surface 56a are arranged in this order in the first axial direction X1. In the orthogonal direction Y, the second fixing surface 55a is farthest from the peripheral wall 13b, followed by the first fixing surface 54a and the third fixing surface 56a in this order. This configuration prevents the first capacitor 731 from coming into contact with the potting compound 75 on the third fixing surface 56a and the first fixing surface 54a. This configuration also prevents the magnetic component 74 from coming into contact with the potting compound 75 on the third fixing surface 56a.

Accordingly, this configuration prevents the capacitors 73 and the magnetic component 74 from causing thickness unevenness of the potting compound 75 by the movement of the capacitors 73 and the magnetic component 74 in the second axial direction X2 with the capacitors 73 and the magnetic component 74 in contact with the potting compound 75. In order to insert the second circuit board 62 with the capacitors 73 and the magnetic component 74 into the projected portion 52, the second circuit board 62 with the capacitors 73 and the magnetic component 74 is moved to a predetermined position within the projected portion 52. In this configuration, the potting compound 75 is present between the first capacitor 731 and the second fixing surface 55a, between the magnetic component 74 and the first fixing surface 54a, and between the second capacitor 732 and the third fixing surface 56a. Then, the first circuit board 61 and the inverter housing 51 are mounted to the housing 11.

This embodiment achieves following advantageous effects.

(1) The second capacitor 732, the magnetic component 74, and the first capacitor 731 protrude from the second circuit board 62 and are arranged in the insertion direction of the second circuit board 62 toward the bottom portion 52b of the projected portion 52 in ascending order of protrusion height from the second circuit board 62, from the most protruding to the least protruding. The projected portion 52 of the housing 11 has the first protrusion portion 54 and the second protrusion portion 55 that cooperate to serve as the protrusion portion of the present disclosure. That is, the protrusion portion of the present disclosure faces and protrudes toward the electronic components in the radial direction of the rotary shaft 14, with the protrusion height of the protrusion portion of the present disclosure increasing in the insertion direction of the second circuit board 62 toward the bottom portion 52b of the projected portion 52 correspondingly with the arrangement of the capacitors 73 and the magnetic component 74. This configuration prevents the first capacitor 731 and the magnetic component 74 from causing thickness unevenness of the potting compound 75 by the movement of the first capacitor 731 and the magnetic component 74 in the second axial direction X2 with the first capacitor 731 and the magnetic component 74 in contact with the potting compound 75. This configuration therefore allows for even thickness of the potting compound 75 between the capacitors 73 and the magnetic component 74 and the first, second, and third fixing surfaces 54a, 55a, and 56a to which the capacitors 73 and the magnetic component 74 are fixed.

(2) The potting compound 75 is provided between the first protrusion portion 54 and the second capacitor 732 facing each other in the axial direction X, and is also provided between the second protrusion portion 55 and the magnetic component 74 facing each other in the axial direction X. The potting compound 75 allows for heat dissipation in the axial direction X.

(3) The plurality of electronic components of the present disclosure includes the pair of capacitors 73 and the magnetic component 74. The magnetic component 74 is located between the capacitors 73 in the axial direction X. This configuration reduces propagation noise between the capacitors 73.

The embodiment may be modified as below. The embodiment and the following modifications may be combined within technically consistent range.

The shape of the inverter housing 51 may be modified. For example, the first cylindrical portion 51a may be formed separately from the closing portion 51b, and connected to the closing portion 51b to form the projected portion 52. In this configuration, for example, the closing portion 51b may be removed from the housing 11 when the second circuit board 62 with the capacitors 73 and the magnetic component 74 is mounted to the housing 11. For example, the second circuit board 62 with the capacitors 73 and the magnetic component 74 may be inserted through the open end of the first cylindrical portion 51a so as to be accommodated in the projected portion 52.

The number of electronic components on the second circuit board 62 is not limited to three. For example, the second circuit board 62 may have thereon two electronic components, or four or more electronic components. In this configuration, the protrusion portion includes protrusion portions in a number corresponding to the number of electronic components. For example, if the second circuit board 62 has two electronic components, one protrusion portion is provided. In this configuration, the potting compound 75 is provided between one of the two electronic components and the protrusion portion and between the other of the two electronic components and the outer peripheral surface of the motor housing 13.

When viewed from the orthogonal direction Y, the capacitors 73 and the magnetic component 74 do not necessarily have to be aligned in a straight line in the axial direction X. For example, when viewed from the orthogonal direction Y, the capacitors 73 and the magnetic component 74 may be offset from each other in the short-side direction of the second circuit board 62.

At least one of the capacitors 73 and the magnetic component 74 may be removed, or another electronic component may be added. In this case, the protrusion portion inside the projected portion 52 includes protrusion portions in a number corresponding to the number of electronic components.

The protrusion portion may be formed separately from and connected to the peripheral wall 13b.

The heat transfer member of the present disclosure is not limited to the potting compound 75, and may be a heat dissipation grease or a heat dissipation sheet.

The compression part 15 is not limited to a scroll compression part including the fixed scroll 20 and the movable scroll 21. The compression part 15 may be a compression part, such as a vane compression part.

The electric compressor 10 does not necessarily have to be a part of the vehicle air conditioner 28. For example, the electric compressor 10 may be mounted in a fuel cell vehicle, and configured to compress air, which serves as the fluid supplied to a fuel cell, with the compression part 15.

What is claimed is:

1. An electric compressor comprising:
a rotary shaft;
a compression part configured to compress a fluid with rotation of the rotary shaft;
a motor configured to drive the compression part;
an inverter configured to drive the motor, the inverter including a first circuit board and a second circuit board, the first circuit board having, on the first circuit board, a driving element for driving the motor, the second circuit board having, on the second circuit board, an electronic component for removing noise from the first circuit board; and
a housing for accommodating the rotary shaft, the compression part, the motor, and the inverter, the housing including: a motor housing having a suction chamber in which the motor is accommodated and into which the fluid is drawn; a compression part housing in which the compression part is accommodated and from which the fluid compressed is discharged; an inverter housing having an inverter accommodation chamber in which the inverter is accommodated; and a partition wall that separates the suction chamber from the inverter accommodation chamber, wherein
the motor housing has a projected portion projecting outward from the motor housing in a radial direction of the rotary shaft and having a bottomed-cylindrical shape with an opening that opens in an axial direction of the rotary shaft, the projected portion extending in an insertion direction of the second circuit board in which the second circuit board is inserted into the projected portion through the opening from a side where the partition wall is located,
the electronic component includes a plurality of the electronic components that protrude from the second circuit board and are arranged in the insertion direction of the second circuit board toward a bottom portion of the projected portion in ascending order of protrusion height from the second circuit board,
the projected portion has a protrusion portion facing the electronic components and protruding toward the electronic components in the radial direction of the rotary shaft, with protrusion height of the protrusion portion increasing in the insertion direction of the second circuit board toward the bottom portion of the projected portion correspondingly with an arrangement of the electronic components, and
a heat transfer member is provided between the protrusion portion and the electronic components.

2. The electric compressor according to claim 1, wherein
the electronic components include a pair of capacitors and a magnetic component,
the magnetic component is located between the capacitors,
the protrusion portion includes a first protrusion portion and a second protrusion portion,
the first protrusion portion faces the magnetic component in the radial direction of the rotary shaft,
the second protrusion portion faces one of the capacitors in the radial direction of the rotary shaft, and is located between the first protrusion portion and the bottom portion of the projected portion, and
the heat transfer member is provided between the first protrusion portion and the magnetic component and between the second protrusion portion and the one of the capacitors.

3. The electric compressor according to claim 2, wherein
the first protrusion portion faces the other of the capacitors in the axial direction of the rotary shaft, and the second protrusion portion faces the magnetic component in the axial direction of the rotary shaft, and
the heat transfer member is provided between the first protrusion portion and the other of the capacitors and between the second protrusion portion and the magnetic component.
